(19) United States
(12) Patent Application Publication
(10) Pub. No.: US 2025/0370324 A1
(43) Pub. Date: Dec. 4, 2025

(54) MULTILAYER REFLECTIVE FILM-ATTACHED SUBSTRATE, REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventors: Masanori NAKAGAWA, Tokyo (JP); Teiichiro UMEZAWA, Tokyo (JP); Yohei IKEBE, Tokyo (JP)

(73) Assignee: HOYA CORPORATION, Tokyo (JP)

(21) Appl. No.: 18/682,747

(22) PCT Filed: Sep. 2, 2022
(86) PCT No.: PCT/JP2022/033127

§ 371 Date: Feb. 10, 2025

(30) Foreign Application Priority Data
Sep. 7, 2021 (JP) 2021-145749

(51) Int. Cl. G03F 1/24; G03F 1/48; G03F 1/54

(52) U.S. Cl. CPC G03F 1/24; G03F 1/48; G03F 1/54

(57) ABSTRACT

Provided is a substrate with a multilayer reflective film comprising a multilayer reflective film having a shallow effective reflective surface and capable of suppressing a phenomenon that atoms to be a material are diffused between a low refractive index layer and a high refractive index layer.

A substrate with a multilayer reflective film comprises a substrate and a multilayer reflective film formed on the substrate, in which the multilayer reflective film comprises a multilayer film in which a low refractive index layer comprising at least one selected from ruthenium (Ru) and rhodium (Rh) and a high refractive index layer comprising silicon (Si) are alternately layered, and the low refractive index layer further comprises an additive element having a work function in a range of more than 3.7 eV and less than 4.7 eV.

### TECHNICAL FIELD

The present invention relates to a substrate with a multilayer reflective film, a reflective mask blank, a reflective mask, and a method for manufacturing a semiconductor device.

### BACKGROUND ART

With a further demand for higher density and higher accuracy of a VLSI device in recent years, extreme ultraviolet (hereinafter referred to as “EUV”) lithography, which is an exposure technique using EUV light, has been proposed.

A reflective mask includes a multilayer reflective film for reflecting exposure light formed on a substrate, and an absorber pattern which is a patterned absorber film formed on the multilayer reflective film for absorbing exposure light. A light image reflected by the multilayer reflective film is transferred onto a semiconductor substrate (transferred object) such as a silicon wafer through a reflective optical system.

As an example of a reflective mask blank for manufacturing a reflective mask, Patent Document 1 describes an EUV blank mask including a substrate, a reflective film layered on the substrate, and an absorption film layered on the reflective film. Patent Document 1 describes that the reflective film has a structure in which a pair including a first layer made of Ru or made of a Ru compound in which one or more elements of Mo, Nb, and Zr are added to Ru and a second layer made of Si is layered a plurality of times.

Patent Document 2 describes a multilayer reflective mirror for soft X-rays and vacuum ultraviolet rays, having a multilayer thin film structure including alternating layers of two types of main materials A and B having different refractive indices. Patent Document 2 describes that at least one sub-material thin film having a function of reducing roughness of a stacking interface is layered between the A layer and the B layer and/or between the B layer and the A layer to form a periodic structure. Patent Document 2 describes that a low refractive index layer is generally formed of a high melting point metal material such as tungsten or molybdenum or a compound containing the high melting point metal material as a main component, and a high refractive index layer is generally formed of a light element such as carbon, silicon, boron, or beryllium or a compound containing the light element as a main component. Furthermore, Patent Document 2 describes that examples of the sub-material include a conductor of a light element having an atomic number of 13 or less, such as carbon C, boron B, beryllium Be, silicon carbide SiC, silicon nitride Si₃N₄, silicon oxide SiO₂, boron nitride BN, boron carbide B₄C, or aluminum nitride AlN, and compounds thereof.

Patent Document 3 describes a multilayer film spectral reflective mirror in which a compound intermediate layer containing Si and C is used between a heavy element layer and a light element layer of a multilayer film spectral element having a Bragg diffraction effect. In addition, Patent Document 3 describes that the multilayer film is prepared using Mo, Ru, Rh, and Re as the heavy element layer, Si as the light element layer, and Si₁₀₀₋ₓCₓ as the intermediate layer.

Patent Document 4 describes a multilayer film X-ray reflective mirror in which a plurality of substance layers are periodically layered. Patent Document 4 describes that an intermediate layer is formed between the substance layers, and a substance having a higher melting point than that of at least one of the substance layers is used as the intermediate layer. In addition, Patent Document 4 describes that a Mo/Si multilayer film is prepared using Mo as a heavy element layer, and Si as a light element layer.

Non Patent Document 1 describes that a B₄C interlayer film (interlayer) is used for a Mo/Si multilayer reflector. In addition, Non Patent Document 1 describes that a Ru/Si multilayer reflective film is used as a multilayer reflector.

### PRIOR ART DOCUMENTS

### Patent Documents

Patent Document 1: JP 2021-110953 A
Patent Document 2: JP H02-242201 A
Patent Document 3: JP H05-203798 A
Patent Document 4: JP H09-230098 A

### Non Patent Document

Non Patent Document 1: Overt Wood et al. “Improved Ru/Si multilayer reflective coatings for advanced extreme-ultraviolet lithography photomasks”. Proc. SPIE 9776, Extreme Ultraviolet (EUV) Lithography VII, 977619 (18 Mar. 2016)

### DISCLOSURE OF INVENTION

The above-described EUV lithography is an exposure technique using extreme ultraviolet light (EUV light). The EUV light refers to light in a wavelength band of a soft X-ray region or a vacuum ultraviolet region, and is specifically light having a wavelength of about 0.2 to 100 nm. In the EUV lithography, EUV light having a wavelength of 13 to 14 nm (for example, a wavelength of 13.5 nm) can be used.

In the EUV lithography, a reflective mask having an absorber pattern is used. EUV light with which the reflective mask is irradiated is absorbed in a portion where the absorber pattern is present, and is reflected in a portion where the absorber pattern is not present. A multilayer reflective film is exposed in the portion where the absorber pattern is not present. The exposed multilayer reflective film reflects the EUV light. In the EUV lithography, a light image reflected by the multilayer reflective film (a portion where the absorber pattern is not present) is transferred onto a semiconductor substrate (transferred object) such as a silicon wafer through a reflective optical system.

As the multilayer reflective film, a multilayer film in which elements having different refractive indices are periodically layered is used. For example, as a multilayer reflective film with respect to EUV light having a wavelength of 13 nm to 14 nm (for example, a wavelength of 13.5 nm), a Mo/Si periodic layered film in which a Mo film having a low refractive index and a Si film having a high refractive index are alternately layered for 40 to 60 periods is used.

In order to achieve high density and high accuracy of a semiconductor device using the reflective mask, a reflection region (surface of a multilayer reflective film) in the reflective mask needs to have a high reflectance with respect to EUV light that is exposure light.

As a node (minimum line width) to be transferred onto a transferred object such as a semiconductor substrate is narrower, an influence of a 3D effect on transfer characteristics is larger. In order to suppress the 3D effect, it is effective to reduce the film thickness of the absorber pattern. However, in the EUV lithography using reflection exposure, it is not sufficient to reduce the thickness of the absorber film for forming the absorber pattern. Therefore, it is also necessary to control a reflective surface on which EUV light is reflected. As the control of the reflective surface, specifically, it is necessary to control the reflective surface such that EUV light reflected from the multilayer reflective film does not spread by bringing an effective reflective surface of the multilayer reflective film as close as possible to a surface. In the present specification, an effective reflective surface relatively close to the surface of the multilayer reflective film may be referred to as a “shallow effective reflective surface”. By presence of the shallow effective reflective surface in the multilayer reflective film, the 3D effect can be suppressed, and the number of layered multilayer reflective films can be reduced.

In order to bring the effective reflective surface of the multilayer reflective film as close as possible to the surface, it is necessary to select a material of the multilayer reflective film so as to increase a reflectance with respect to EUV light. The multilayer reflective film has a stack of a low refractive index layer and a high refractive index layer, and thus reflects EUV light. When the material of the multilayer reflective film is selected so as to increase the reflectance with respect to EUV light, depending on the material, a phenomenon that atoms to be the material are diffused between the low refractive index layer and the high refractive index layer may occur. When such a diffusion phenomenon occurs, the reflectance of the multilayer reflective film decreases.

Therefore, an object of the present invention is to provide a substrate with a multilayer reflective film, a reflective mask blank, and a reflective mask, including a multilayer reflective film having a shallow effective reflective surface and capable of suppressing a phenomenon that atoms to be a material are diffused between a low refractive index layer and a high refractive index layer. Another object of the present invention is to provide a method for manufacturing a semiconductor device using the reflective mask.

In order to solve the above problems, the present invention has the following configurations.

### (Configuration 1)

Configuration 1 of the present invention is a substrate with a multilayer reflective film comprising a substrate and a multilayer reflective film formed on the substrate, in which
the multilayer reflective film comprises a multilayer film in which a low refractive index layer comprising at least one selected from ruthenium (Ru) and rhodium (Rh) and a high refractive index layer comprising silicon (Si) are alternately layered, and
the low refractive index layer further comprises an additive element having a work function in a range of more than 3.7 eV and less than 4.7 eV.

### (Configuration 2)

Configuration 2 of the present invention is the substrate with a multilayer reflective film according to configuration 1, in which the low refractive index layer comprises at least one additive element selected from thallium (TI), hafnium (Hf), titanium (Ti), zirconium (Zr), manganese (Mn), indium (In), gallium (Ga), cadmium (Cd), bismuth (Bi), tantalum (Ta), lead (Pb), silver (Ag), aluminum (Al), vanadium (V), niobium (Nb), tin (Sn), zinc (Zn), mercury (Hg), chromium (Cr), iron (Fe), antimony (Sb), tungsten (W), molybdenum (Mo), and copper (Cu).

### (Configuration 3)

Configuration 3 of the present invention is the substrate with a multilayer reflective film according to configuration 1 or 2, in which when a stack of the low refractive index layer and the high refractive index layer is taken as one period, the stack is layered for less than 40 periods.

### (Configuration 4)

Configuration 4 of the present invention is the substrate with a multilayer reflective film according to any one of configurations 1 to 3, comprising a protective film on the multilayer reflective film.

### (Configuration 5)

Configuration 5 of the present invention is the substrate with a multilayer reflective film according to configuration 4, in which the protective film comprises the same material as the low refractive index layer.

### (Configuration 6)

Configuration 6 of the present invention is the substrate with a multilayer reflective film according to configuration 4 or 5, in which the protective film comprises at least one selected from ruthenium (Ru) and rhodium (Rh), and the same additive element as the low refractive index layer.

### (Configuration 7)

Configuration 7 of the present invention is a reflective mask blank comprising an absorber film on the protective film of the substrate with a multilayer reflective film according to any one of configurations 4 to 6.

### (Configuration 8)

Configuration 8 of the present invention is a reflective mask blank comprising an absorber film on the multilayer reflective film of the substrate with a multilayer reflective film according to any one of configurations 1 to 3.

### (Configuration 9)

Configuration 9 of the present invention is a reflective mask comprising an absorber pattern obtained by patterning the absorber film of the reflective mask blank according to configuration 7 or 8.

### (Configuration 10)

Configuration 10 of the present invention is a method for manufacturing a semiconductor device, comprising performing a lithography process with an exposure apparatus using the reflective mask according to configuration 9 to form a transfer pattern on a transferred object.

The present invention can provide a substrate with a multilayer reflective film, a reflective mask blank, and a reflective mask, including a multilayer reflective film having a shallow effective reflective surface and capable of suppressing a phenomenon that atoms to be a material are diffused between a low refractive index layer and a high refractive index layer. In addition, the present invention can provide a method for manufacturing a semiconductor device using the reflective mask.

### BRIEF DESCRIPTION OF DRAWINGS

FIG. 1 is a schematic cross-sectional view illustrating an example of a substrate with a multilayer reflective film of the present embodiment.

FIG. 2 is a schematic cross-sectional view illustrating another example of the substrate with a multilayer reflective film of the present embodiment.

FIG. 3 is a schematic cross-sectional view illustrating an example of a reflective mask blank of the present embodiment.

FIG. 4 is a schematic cross-sectional view illustrating another example of the reflective mask blank of the present embodiment.

FIG. 5 is a schematic cross-sectional view illustrating still another example of the reflective mask blank of the present embodiment.

FIGS. 6A to 6D are schematic cross-sectional views illustrating an example of a method for manufacturing a reflective mask of the present embodiment.

FIG. 7 is a diagram illustrating a relationship between an atomic number of a metal element and a work function.

FIG. 8 is a diagram illustrating a relationship between a refractive index (n) and an extinction coefficient (k) of an additive element.

FIG. 9 is a schematic diagram illustrating an example of an EUV exposure apparatus.

### DESCRIPTION OF EMBODIMENTS

Hereinafter, an embodiment of the present invention will be specifically described with reference to the drawings. Note that the following embodiment is a mode for specifically describing the present invention and does not limit the present invention within the scope thereof.

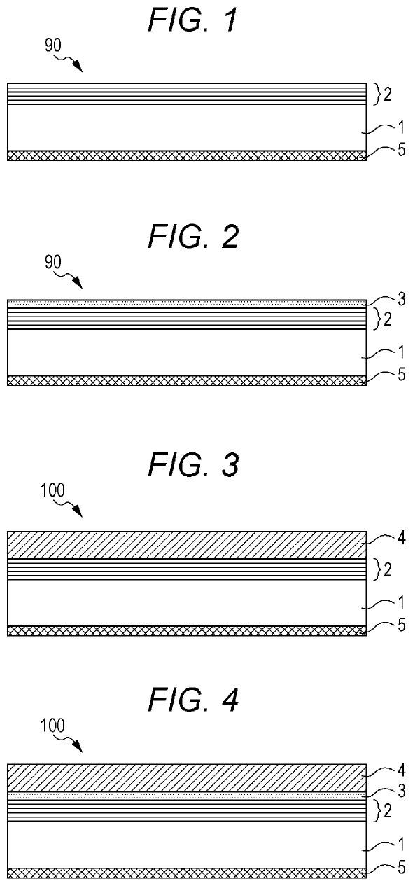

FIG. 1 is a schematic cross-sectional view illustrating an example of a substrate with a multilayer reflective film 90 of the present embodiment. The substrate with a multilayer reflective film 90 of the present embodiment includes a substrate 1 and a multilayer reflective film 2 formed on the substrate 1. The multilayer reflective film 2 includes a multilayer film in which a predetermined low refractive index layer and a predetermined high refractive index layer are alternately layered. A conductive back film 5 for electrostatic chuck may be formed on a back surface of the substrate 1 (surface opposite to a side where the multilayer reflective film 2 is formed).

FIG. 2 is a schematic cross-sectional view illustrating another example of the substrate with a multilayer reflective film 90 according to the present embodiment. The substrate with a multilayer reflective film 90 illustrated in FIG. 2 includes the substrate 1, the multilayer reflective film 2 formed on the substrate 1, and a protective film 3 formed on the multilayer reflective film 2. A conductive back film 5 for electrostatic chuck may be formed on a back surface of the substrate 1 (surface opposite to a side where the multilayer reflective film 2 is formed).

In the present specification, “a thin film B is disposed (formed) on a thin film A (or substrate)” includes not only a case where the thin film B is disposed (formed) in contact with a surface of the thin film A (or substrate) but also a case where there is another thin film C between the thin film A (or substrate) and the thin film B. In addition, in the present specification, for example, “a thin film B (or substrate) is disposed in contact with a surface of a thin film A” means that the thin film A (or substrate) and the thin film B are disposed in direct contact with each other without another thin film interposed between the thin film A (or substrate) and the thin film B. In addition, in the present specification, “on” does not necessarily mean an upper side in the vertical direction. “On” merely indicates a relative positional relationship among a thin film, a substrate, and the like.

The substrate with a multilayer reflective film 90 of the present embodiment will be specifically described.

### <Substrate |>

As the substrate 1, a substrate having a low thermal expansion coefficient within a range of 0±5 ppb/° C., is preferably used in order to prevent distortion of a transfer pattern due to heat during exposure to EUV light. As a material having a low thermal expansion coefficient within this range, for example, SiO₂—TiO₂-based glass or multicomponent-based glass ceramic can be used.

A main surface (first main surface) of the substrate 1 on a side where a transfer pattern (absorber pattern 4a described later) is formed is preferably processed in order to increase a flatness. By increasing the flatness of the main surface of the substrate 1, position accuracy and transfer accuracy of the pattern can be increased. For example, in a case of EUV exposure, the flatness in a region of 132 mm×132 mm of the main surface of the substrate 1 on the side where the transfer pattern is formed is preferably 0.1 μm or less, more preferably 0.05 μm or less, and particularly preferably 0.03 μm or less. In addition, a second main surface (back surface) opposite to the side where the transfer pattern is formed is a surface to be fixed to an exposure apparatus by electrostatic chuck. The flatness in a region of 142 mm×142 mm of the back surface is preferably 0.1 μm or less, more preferably 0.05 μm or less, and particularly preferably 0.03 μm or less. Note that, in the present specification, the flatness is a value representing warpage (deformation amount) of a surface indicated by total indicated reading (TIR). The flatness (TIR) is an absolute value of a difference in height between the highest position of a surface of the substrate 1 above a focal plane and the lowest position of the surface of the substrate 1 below the focal plane, in which the focal plane is a plane defined by a minimum square method using the surface of the substrate 1 as a reference.

In a case of EUV exposure, the main surface of the substrate 1 on a side where the transfer pattern is formed preferably has a surface roughness of 0.1 nm or less in terms of root mean square roughness (Rq). Note that the surface roughness can be measured with an atomic force microscope.

The substrate 1 preferably has high rigidity in order to prevent deformation due to film stress of a thin film (such as the multilayer reflective film 2) formed on the substrate 1. In particular, the substrate 10 preferably has a high Young's modulus of 65 GPa or more.

### <Multilayer Reflective Film 2>

The multilayer reflective film 2 has a structure in which a plurality of layers mainly containing elements having different refractive indices is periodically layered. Generally, the multilayer reflective film 2 includes a multilayer film in which a thin film (high refractive index layer) of a light element that is a high refractive index material or a compound of the light element and a thin film (low refractive index layer) of a heavy element that is a low refractive index material or a compound of the heavy element are alternately layered.

In order to form the multilayer reflective film 2, the high refractive index layer and the low refractive index layer can be layered in this order from the substrate 1 side for a plurality of periods. In this case, one (high refractive index layer/low refractive index layer) stack is one period.

The multilayer reflective film 2 of the present embodiment includes a multilayer film in which a low refractive index layer containing at least one selected from ruthenium (Ru) and rhodium (Rh) and a high refractive index layer containing silicon (Si) are alternately layered.

In the present embodiment, the high refractive index layer contains silicon (Si). The high refractive index layer may contain a simple substance of Si or a Si compound. The Si compound may contain Si and at least one element selected from the group consisting of B, C, N, O, and H. By using the layer containing Si as the high refractive index layer, the multilayer reflective film 2 having an excellent reflectance with respect to EUV light can be obtained. In order to obtain a relatively high reflectance, the high refractive index layer preferably contains silicon (Si). Note that “the high refractive index layer contains silicon (Si)” does not exclude presence of impurities other than Si inevitably mixed in the high refractive index layer. The same applies to other thin films and other elements.

In the present embodiment, the low refractive index layer contains at least one selected from ruthenium (Ru) and rhodium (Rh). By inclusion of ruthenium (Ru) and/or rhodium (Rh) in the low refractive index layer, a shallower effective reflective surface than that of a conventional Mo/Si multilayer reflective film can be obtained.

As a node (minimum line width) to be transferred onto a transferred object such as a semiconductor substrate is narrower, an influence of a 3D effect on transfer characteristics is larger. The 3D effect means that a three-dimensional structure including a structure of a reflective mask 200 in a height direction affects fidelity of a transfer pattern with respect to a mask pattern. In EUV lithography, in order to suppress the 3D effect, it is necessary to control a reflective surface of the reflective mask 200. As the control of the reflective surface, specifically, it is necessary to bring an effective reflective surface of the multilayer reflective film 2 as close as possible to a surface. By presence of the shallow effective reflective surface in the reflective mask 200, it is possible to control the EUV light reflected from the multilayer reflective film 2 so as not to spread, and therefore the 3D effect can be suppressed. By inclusion of a multilayer film in which a low refractive index layer containing at least one selected from ruthenium (Ru) and rhodium (Rh) and a high refractive index layer containing silicon (Si) are alternately layered in the multilayer reflective film 2, the effective reflective surface of the multilayer reflective film 2 can be made shallower than that of the conventional Mo/Si multilayer reflective film.

Meanwhile, when Ru and/or Rh is used as the material of the low refractive index layer, there may be a problem that Si of the high refractive index layer is diffused and a reflectance of the multilayer reflective film 2 with respect to EUV light decreases. In the present embodiment, by further inclusion of a predetermined additive element in addition to Ru and/or Rh in the low refractive index layer, occurrence of this problem can be suppressed.

The low refractive index layer of the substrate with a multilayer reflective film 90 of the present embodiment further contains an additive element having a work function in a range of more than 3.7 eV and less than 4.7 eV as the predetermined additive element. Note that since Ru has a work function of 4.71 eV and Rh has a work function of 4.98 eV, the work function of the additive element is lower than the work function of Ru. Therefore, by adding the additive element to the low refractive index layer, diffusion of the material (Si) of the high refractive index layer into the low refractive index layer can be suppressed. Meanwhile, when the high refractive index layer contains an element having a work function equal to or larger than the work function of Ru, there is a problem that Si in the high refractive index layer is diffused into the low refractive index layer. In addition, since Mg has a work function of 3.66 eV, the work function of the additive element is higher than that of Mg. When an element having a work function equal to or lower than the work function of Mg is added to the low refractive index layer, it is difficult to manufacture a pure metal target for film formation by sputtering. Therefore, the work function of the additive element needs to be in the above-described range. The work function of the additive element means a work function of not an alloy but a metal containing one type of additive element.

Note that the work function is considered to be a difference between a vacuum level and a Fermi level. Therefore, the additive element can also be selected on the basis of the magnitude of the Fermi level of a metal. That is, the additive element contained in the low refractive index layer is a metal element having a Fermi level higher than the Fermi level of Ru and lower than the Fermi level of magnesium (Mg).

Silicon (Si), which is a material of the high refractive index layer, is known to be easily diffused into a metal. Ease of diffusion of Si into a metal depends on a work function of the metal. That is, when the work function of the metal of the low refractive index layer increases. Si is easily diffused into the metal (low refractive index layer). As a result, a reflectance of the multilayer reflective film 2 with respect to EUV light decreases. The decrease in reflectance may occur particularly significantly after annealing of the multilayer reflective film 2. Conversely, when the work function of the metal decreases. Si is less likely to be diffused into the metal (low refractive index layer). Therefore, the additive element contained in the low refractive index layer for forming the multilayer reflective film 2 in combination with the high refractive index layer containing Si is preferably a metal having a small work function.

Similarly, when a Si thin film and a metal thin film are in contact with each other, adhesion between the Si thin film and the metal thin film decreases as the work function of the metal increases. Conversely, when the work function of the metal decreases, the adhesion between the Si thin film and the metal thin film increases. Therefore, the additive element contained in the low refractive index layer for forming the multilayer reflective film 2 in combination with the high refractive index layer containing Si is preferably a metal having a small work function.

From the above, it can be understood that diffusion of Si into the low refractive index layer can be reduced in a case of a low refractive index layer containing an additive element having a work function smaller than 4.71 eV, which is a work function of Ru, as compared with cases of a low refractive index layer containing only Ru, a low refractive index layer containing only Rh, and a low refractive index layer containing only RuRh. In addition, it can be understood that adhesion between the low refractive index layer and the high refractive index layer can be improved.

In addition, in a case of Si of an intrinsic semiconductor not doped with impurities, a work function of Si is 4.61 eV (difference between a vacuum level and just a middle of a band gap (Fermi level)). By using a metal having a work function lower than the work function of Si as the additive element, diffusion of Si into the low refractive index layer can be more reliably suppressed.

As described above, by using a low refractive index layer made of a material obtained by adding a predetermined additive element to Ru and/or Rh, the multilayer reflective film 2 has a shallow effective reflective surface, and it is possible to suppress a phenomenon that Si atoms are diffused from the high refractive index layer containing Si to the low refractive index layer. As a result, it is possible to suppress a decrease in the reflectance of the multilayer reflective film 2 of the substrate with a multilayer reflective film 90 with respect to EUV light. In addition, adhesion between the low refractive index layer and the high refractive index layer of the multilayer reflective film 2 can be improved.

FIG. 7 illustrates a relationship between an atomic number of a metal element and a work function. An element inside a quadrangle indicated by a broken line in FIG. 7 is a metal element having a work function in a range of more than 3.7 eV and less than 4.7 eV. By inclusion of these metal elements as additive elements in the low refractive index layer, a phenomenon that Si atoms are diffused from the high refractive index layer containing Si to the low refractive index layer can be suppressed, and adhesion between the low refractive index layer and the high refractive index layer can be improved.

Table 2 presents a list of additive elements contained in the low refractive index layer of the multilayer reflective film 2 of the substrate with a multilayer reflective film 90 of the present embodiment. Table 2 presents a work function, a refractive index (n), and an extinction coefficient (k) of each additive element. Note that, in the present specification, the additive element may be referred to as “X”. For example, when the low refractive index layer contains Ru and an additive element as materials, the materials of the low refractive index layer may be referred to as RuX.

In the present embodiment, the low refractive index layer contains at least one additive element selected from thallium (TI), hafnium (Hf), titanium (Ti), zirconium (Zr), manganese (Mn), indium (In), gallium (Ga), cadmium (Cd), bismuth (Bi), tantalum (Ta), lead (Pb), silver (Ag), aluminum (Al), vanadium (V), niobium (Nb), tin (Sn), zinc (Zn), mercury (Hg), chromium (Cr), iron (Fe), antimony (Sb), tungsten (W), molybdenum (Mo), and copper (Cu). Work functions of these additive elements are in a range of more than 3.7 eV and less than 4.7 eV. Therefore, a phenomenon that Si atoms are diffused from the high refractive index layer containing Si to the low refractive index layer can be suppressed, and adhesion between the low refractive index layer and the high refractive index layer can be improved.

An additive element having a low work function can further reduce diffusion of Si into the low refractive index layer. Therefore, the additive elements can be classified into three diffusion preventing groups depending on the magnitude of the work function. An additive element included in a diffusion preventing group A is an additive element having a work function of more than 3.7 eV and 4.3 eV or less. An additive element included in a diffusion preventing group B is an additive element having a work function of more than 4.3 eV and 4.5 eV or less. An additive element included in a diffusion preventing group C is an additive element having a work function of more than 4.5 eV and less than 4.7 eV. A diffusion preventing group of each additive element is presented in a “diffusion preventing group” column of Table 2.

Note that the additive elements belonging to the diffusion preventing group A are Tl, Hf, Ti, Zr, Mn, In, Ga, Cd, Bi, Ta, Pb, Ag, Al, V, Nb, and Sn. The additive elements belonging to the diffusion preventing group B are Zn, Hg, Cr, and Fe. The additive elements belonging to the diffusion preventing group C are Sb, W, Mo, and Cu.

When the addition amount of an additive element to the low refractive index layer is small, diffusion of Si into the low refractive index layer is likely to occur, and therefore the reflectance of the multilayer reflective film 2 may decrease. In order to suppress the diffusion of Si into the low refractive index layer, the additive elements belonging to the diffusion preventing groups A, B, or C can have a lower limit of the addition amount to the low refractive index layer. The addition amount of an additive element of the diffusion preventing group A is preferably 1 atom % or more, and more preferably 3 atom % or more. The addition amount of an additive element of the diffusion preventing group B is preferably 4 atom % or more, and more preferably 7 atom % or more. The addition amount of an additive element of the diffusion preventing group C is preferably 8 atom % or more, and more preferably 12 atom % or more. A lower limit of the addition amount is presented in a “lower limit (atom %)” column of Table 2.

In addition, a ratio of the content of an additive element of the diffusion preventing group A to the content of a main material (Ru content. Rh content, or RuRh content) of the low refractive index layer (content of additive element/content of main material) is preferably 0.01 or more, and more preferably 0.03 or more. A ratio of the content of an additive element of the diffusion preventing group B to the content of the main material of the low refractive index layer is preferably 0.04 or more, and more preferably 0.08 or more. A ratio of the content of an additive element of the diffusion preventing group C to the content of the main material of the low refractive index layer is preferably 0.09 or more, and more preferably 0.13 or more.

In order to suppress diffusion of Si into the low refractive index layer, the additive element is preferably an additive element belonging to the diffusion preventing groups A or B, and more preferably an additive element belonging to the diffusion preventing group A. In addition, a plurality of additive elements may be selected from the diffusion preventing groups A, B, and/or C.

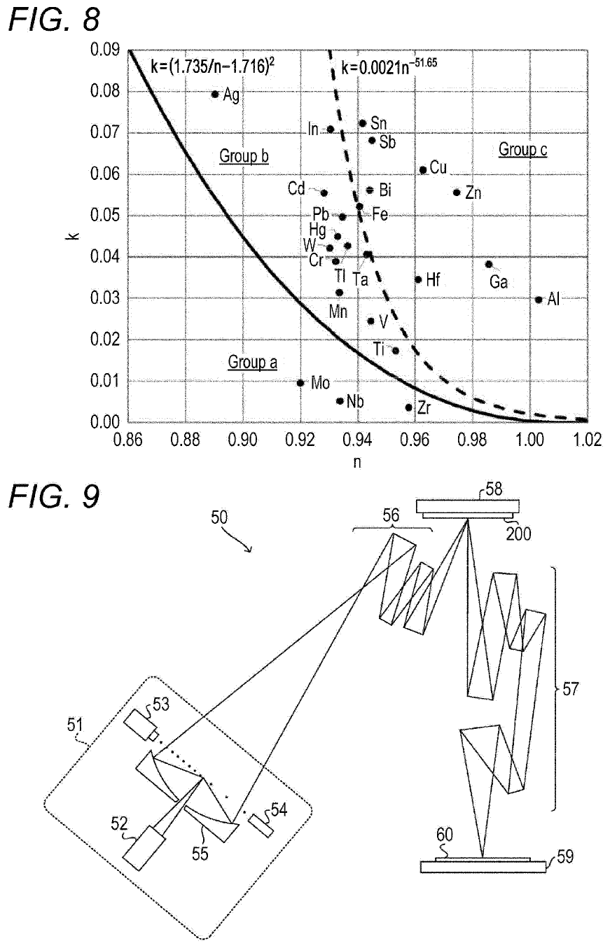

FIG. 8 illustrates a relationship between a refractive index (n) and an extinction coefficient (k) of an additive element. In FIG. 8, a curve indicated by a solid line indicates that a relationship between the refractive index (n) and the extinction coefficient (k) is as follows:

$$k = {( 1.73 5 / n - 1.716 )}^{2} \qquad Formula ( 1 )$$

In a case where the material of the low refractive index layer has a refractive index (n) and an extinction coefficient (k) on the solid line of formula (1), when the multilayer reflective film 2 having a stack of the low refractive index layer and a high refractive index layer of Si is formed, a reflectance of the multilayer reflective film 2 with respect to EUV light having a wavelength of 13.5 nm can be predicted to be 50% by simulation. Note that, in the simulation, two layers in which one high refractive index layer (Si) and one low refractive index layer having a refractive index (n) of 0.88 or more and 0.96 or less and an extinction coefficient (k) of 0 or more and 0.08 or less are layered in this order were taken as one period, and a multilayer film in which the stack was layered for 40 periods was used as a model. In addition, regarding the “reflectance with respect to EUV light having a wavelength of 13.5 nm”, in the above simulation, the film thickness of the high refractive index layer was made variable in a range of 0 nm or more and 6 nm or less and the film thickness of the low refractive index layer was made variable in a range of 0 nm or more and 6 nm or less, and a calculated maximum reflectance was used.

In addition, in FIG. 8, a curve indicated by a broken line indicates that a relationship between the refractive index (n) and the extinction coefficient (k) is as follows:

$$k = 0.002 {ln}^{- 51.65} \qquad Formula ( 2 )$$

In a case where the material of the low refractive index layer has a refractive index (n) and an extinction coefficient (k) on the broken line of formula (2), when the multilayer reflective film 2 having a stack of the low refractive index layer and a high refractive index layer of Si is formed, a reflectance of the multilayer reflective film 2 with respect to EUV light having a wavelength of 13.5 nm can be predicted to be 35% by simulation. Note that, in the simulation, two layers in which one high refractive index layer (Si) and one low refractive index layer having a refractive index (n) of 0.88 or more and 0.96 or less and an extinction coefficient (k) of 0 or more and 0.08 or less are layered in this order were taken as one period, and a multilayer film in which the stack was layered for 40 periods was used as a model. In addition, regarding the “reflectance with respect to EUV light having a wavelength of 13.5 nm”, in the above simulation, the film thickness of the high refractive index layer was made variable in a range of 0) nm or more and 6 nm or less and the film thickness of the low refractive index layer was made variable in a range of 0) nm or more and 6 nm or less, and a calculated maximum reflectance was used.

FIG. 8 illustrates a relationship between a refractive index (n) and an extinction coefficient (k) of each additive element. The reflectance with respect to EUV light having a wavelength of 13.5 nm can be predicted from values of a refractive index (n) and an extinction coefficient (k) of an additive element. For example, in a case of the multilayer reflective film 2 including a Mo low refractive index layer and a Si high refractive index layer, the reflectance of the multilayer reflective film 2 with respect to the EUV light can be predicted from values of a refractive index (n) and an extinction coefficient (k) of Mo illustrated in FIG. 8. Note that, in the model for predicting the reflectance, two layers in which one high refractive index layer (Si) and one low refractive index layer are layered in this order are taken as one period, and a multilayer film in which the stack is layered for 40 periods is used, and the reflectance is a predicted maximum reflectance when the film thickness of the high refractive index layer is variable in a range of 0) nm or more and 6 nm or less and the film thickness of the low refractive index layer is variable in a range of 0 nm or more and 6 nm or less. Note that FIG. 8 illustrates prediction in a case where the number of stacked layers in the multilayer reflective film 2 is 40 periods, but it can be said that a similar tendency is obtained even in a case where the number of stacked layers is less than 40 periods, for example, about 35 periods.

From the relationship illustrated in FIG. 8, the additive elements can be classified into three optical characteristic groups depending on influences of the additive elements on the reflectance. An additive element included in an optical characteristic group a (indicated as “Group a” in FIG. 8) is an additive element having a reflectance higher than that of the solid line (reflectance 50%) of formula (1). An additive element included in an optical characteristic group b (indicated as “Group b” in FIG. 8) is an additive element having a reflectance lower than that of the solid line (reflectance 50%) of formula (1) and higher than that of the broken line (reflectance 35%) of formula (2). An additive element included in an optical characteristic group c (indicated as “Group c” in FIG. 8) is an additive element having a reflectance lower than that of the broken line (reflectance 35%) of formula (2). An optical characteristic group of each additive element is presented in an “optical characteristic group” column of Table 2.

In order to keep the reflectance of the multilayer reflective film 2 with respect to EUV light high, the addition amount of an additive element to the low refractive index layer can have an upper limit. This is because the reflectance of the multilayer reflective film 2 decreases when the addition amount of an additive element to the low refractive index layer is large. The addition amount of an additive element of the optical characteristic group a is preferably 50 atom % or less, and more preferably 40 atom % or less. The addition amount of an additive element of the optical characteristic group b is preferably 30 atom % or less, and more preferably 20 atom % or less. The addition amount of an additive element of the optical characteristic group c is preferably 15 atom % or less, and more preferably 10 atom % or less. An upper limit of the addition amount is presented in an “upper limit (atom %)” column of Table 2.

In addition, a ratio of the content of an additive element of the optical characteristic group a to the content of a main material (Ru content, Rh content, or RuRh content) of the low refractive index layer (content of additive element/content of main material) is preferably 0.56 or less, and more preferably 0.44 or less. A ratio of the content of an additive element of the optical characteristic group b to the content of the main material of the low refractive index layer is preferably 0.33 or less, and more preferably 0.22 or less. A ratio of the content of an additive element of the optical characteristic group c to the content of the main material of the low refractive index layer is preferably 0.17 or less, and more preferably 0.11 or less.

Note that the additive elements belonging to the optical characteristic group a are zirconium (Zr), niobium (Nb), and molybdenum (Mo). The additive elements belonging to the optical characteristic group b are thallium (TI), titanium (Ti), manganese (Mn), indium (In), cadmium (Cd), tantalum (Ta), lead (Pb), silver (Ag), vanadium (V), mercury (Hg), chromium (Cr), and tungsten (W). The additive elements belonging to the optical characteristic group c are hafnium (Hf), gallium (Ga), bismuth (Bi), aluminum (Al), tin (Sn), zinc (Zn), iron (Fe), antimony (Sb), and copper (Cu).

In order to obtain good optical characteristics, the additive element is preferably an additive element belonging to the optical characteristic groups a or b, and more preferably an additive element belonging to the optical characteristic group a. In addition, a plurality of additive elements may be selected from the optical characteristic groups a, b, and/or c.

From the above, a preferred range of the content of the additive element in the low refractive index layer is as presented in Table 2. In addition, when Tl is used as the additive element, the content of the main material (Ru content. Rh content, or RuRh content) of the low refractive index layer is preferably more than 70 atom % and less than 99 atom %. When Hf is used as the additive element, the content of the main material is preferably more than 85 atom % and less than 99 atom %. When Ti is used as the additive element, the content of the main material is preferably more than 70 atom % and less than 99 atom %. When Zr is used as the additive element, the content of the main material is preferably more than 50 atom % and less than 99 atom %. When Mn is used as the additive element, the content of the main material is preferably more than 70 atom % and less than 99 atom %. When In is used as the additive element, the content of the main material is preferably more than 70 atom % and less than 99 atom %. When Ga is used as the additive element, the content of the main material is preferably more than 85 atom % and less than 99 atom %. When Cd is used as the additive element, the content of the main material is preferably more than 70 atom % and less than 99 atom %. When Bi is used as the additive element, the content of the main material is preferably more than 85 atom % and less than 99 atom %. When Ta is used as the additive element, the content of the main material is preferably more than 70 atom % and less than 99 atom %. When Pb is used as the additive element, the content of the main material is preferably more than 70 atom % and less than 99 atom %. When Ag is used as the additive element, the content of the main material is preferably more than 70 atom % and less than 99 atom %. When Al is used as the additive element, the content of the main material is preferably more than 85 atom % and less than 99 atom %. When V is used as the additive element, the content of the main material is preferably more than 70) atom % and less than 99 atom %. When Nb is used as the additive element, the content of the main material is preferably more than 50 atom % and less than 99 atom %. When Sn is used as the additive element, the content of the main material is preferably more than 85 atom % and less than 99 atom %. When Zn is used as the additive element, the content of the main material is preferably more than 85 atom % and less than 96 atom %. When Hg is used as the additive element, the content of the main material is preferably more than 70 atom % and less than 96 atom %. When Cr is used as the additive element, the content of the main material is preferably more than 70) atom % and less than 96 atom %. When Fe is used as the additive element, the content of the main material is preferably more than 85 atom % and less than 96 atom %. When Sb is used as the additive element, the content of the main material is preferably more than 85 atom % and less than 92 atom %. When W is used as the additive element, the content of the main material is preferably more than 70 atom % and less than 92 atom %. When Mo is used as the additive element, the content of the main material is preferably more than 50 atom % and less than 92 atom %. When Cu is used as the additive element, the content of the main material is preferably more than 85 atom % and less than 92 atom %.

When an alloy of a plurality of elements is used as the additive element, an appropriate blending amount of the alloy as the additive element in the low refractive index layer can be estimated on the basis of the appropriate content of each additive element described above and the blending amount of each element in the alloy. Note that it is preferable that the low refractive index layer does not contain an element other than Ru and Rh as main materials and the additive elements described in Table 2. This is because, in a case where the low refractive index layer contains an element other than the main materials and the additive elements, there is a high possibility that Si in the high refractive index layer may be diffused into the low refractive index layer. Therefore, the low refractive index layer preferably contains only Ru and/or Rh and a predetermined additive element.

In the substrate with a multilayer reflective film 90 according to the present embodiment, when a stack of the low refractive index layer and the high refractive index layer is taken as one period, the stack is layered for less than 40 periods. The stack of the multilayer reflective film 2 is layered preferably for 35 periods or less, more preferably for 30 periods or less. Since the effective reflective surface of the multilayer reflective film 2 of the present embodiment is shallow; an appropriate reflectance can be obtained with a smaller number of periods than that of a conventional multilayer reflective film. Therefore, by using the substrate with a multilayer reflective film 90 of the present embodiment, the 3D effect can be suppressed. Note that in order to make the multilayer reflective film 2 to have an appropriate reflectance, the stack is layered preferably for 20 periods or more, more preferably for 25 periods or more.

When the multilayer reflective film 2 is formed, the high refractive index layer can be first formed on a surface of the substrate 1, and then the low refractive index layer can be formed. In this case, the multilayer reflective film 2 has a stack having a predetermined number of periods when the high refractive index layer and the low refractive index layer are taken as one period on the substrate 1. An uppermost layer of the multilayer reflective film 2 is the low refractive index layer. In a case of the multilayer reflective film 2 having this structure, when the low refractive index layer constitutes an outermost surface of the multilayer reflective film 2, the low refractive index layer is easily oxidized depending on a material constituting the low refractive index layer, and the reflectance of the reflective mask 200 may decrease. Therefore, it is preferable to further form a high refractive index layer on the low refractive index layer that is the uppermost layer to form the multilayer reflective film 2. Instead of the high refractive index layer, a Si layer containing Si as a material can be formed on the low refractive index layer as the uppermost layer.

When the multilayer reflective film 2 is formed, the low refractive index layer can be first formed on a surface of the substrate 1, and then the high refractive index layer can be formed. In this case, the multilayer reflective film 2 has a stack having a predetermined number of periods when the low refractive index layer and the high refractive index layer are taken as one period on the substrate 1. In a case of this structure, since the uppermost layer is the high refractive index layer, this structure may be left as it is.

Note that, as described above, when the uppermost layer of the multilayer reflective film 2 is the high refractive index layer, it is preferable to form a protective film 3 described later on the multilayer reflective film 2.

Meanwhile, when the low refractive index layer of the multilayer reflective film 2 of the present embodiment contains ruthenium (Ru), the uppermost layer of the multilayer reflective film 2 can be the low refractive index layer. This is because Ru has a function of protecting the multilayer reflective film 2 from dry etching and cleaning in a reflective mask 200 manufacturing process described later. In this case, the low refractive index layer as the uppermost layer can also function as the protective film 3.

From the above, the structure of the multilayer reflective film 2 is preferably a structure in which the low refractive index layer contains Ru, and is preferably a structure in which the high refractive index layer and the low refractive index layer containing Ru are layered in this order from the substrate 1 side, and the uppermost layer is the low refractive index layer. Note that the film thickness and composition of the low refractive index layer as the uppermost layer can be appropriately adjusted from a viewpoint of dry etching resistance and cleaning resistance. Note that in order to obtain the multilayer reflective film 2 having a high reflectance, the film thickness and composition of the low refractive index layer as the uppermost layer are preferably the same as the film thickness and composition of another low refractive index layer.

The reflectance of the multilayer reflective film 2 alone used in the present embodiment is, for example, 65% or more. An upper limit of the reflectance of the multilayer reflective film 2 is, for example, 73%. Note that the thicknesses and period of layers included in the multilayer reflective film 2 can be selected so as to satisfy Bragg's law: In a case of the multilayer reflective film 2 for reflecting EUV light having a wavelength of 13.5 nm, the film thickness of one period (one pair of high refractive index layer and low refractive index layer) is preferably about 7 nm.

The multilayer reflective film 2 can be formed by a known method. The multilayer reflective film 2 can be formed by, for example, an ion beam sputtering method, a magnetron sputtering method, a reactive sputtering method, or the like.

For example, when the multilayer reflective film 2 is a RuNb/Si multilayer film containing Nb as the additive element of the low refractive index layer, a RuNb film having a thickness of about 3 nm is formed on the substrate 1 by an ion beam sputtering method using a RuNb target. Next, a Si film having a thickness of about 4 nm is formed using a Si target. By repeating such an operation, the multilayer reflective film 2 in which a RuNb/Si film is layered for 20 to 39 periods can be formed. At this time, a surface layer of the multilayer reflective film 2 opposite to the substrate 1 is a layer containing Si (Si film). The thickness of the RuNb/Si film for one period is preferably 7 nm.

### <Protective Film 3>

As illustrated in FIG. 2, the substrate with a multilayer reflective film 90 of the present embodiment preferably includes the protective film 3 formed on the multilayer reflective film 2.

The protective film 3 can be formed on the multilayer reflective film 2 or in contact with a surface of the multilayer reflective film 2 in order to protect the multilayer reflective film 2 from dry etching and cleaning in a reflective mask 200 manufacturing process described later. In addition, the protective film 3 has a function of protecting the multilayer reflective film 2 when a black defect in a transfer pattern (absorber pattern 4a) is corrected using an electron beam (EB). By forming the protective film 3 on the multilayer reflective film 2, damage to the surface of the multilayer reflective film 2 can be suppressed when the reflective mask 200 is manufactured. As a result, a reflectance characteristic of the multilayer reflective film 2 with respect to EUV light is improved.

FIG. 2 illustrates a case where the protective film 3 has one layer. However, the protective film 3 can have a stack of two layers. In addition, the protective film 3 can have a stack of three or more layers, a lowermost layer and an uppermost layer may be made of, for example, a substance containing Ru, and a metal other than Ru or an alloy may be interposed between the lowermost layer and the uppermost layer. The protective film 3 is made of, for example, a material containing ruthenium as a main component. Examples of the material containing ruthenium as a main component include a Ru metal simple substance, a Rh metal simple substance, a Ru alloy containing Ru and at least one metal selected from titanium (Ti), niobium (Nb), rhodium (Rh), molybdenum (Mo), zirconium (Zr), yttrium (Y), boron (B), lanthanum (La), cobalt (Co), and rhenium (Re), and a material containing a Ru metal simple substance, a Rh metal simple substance, or a Ru alloy, and nitrogen.

A Ru content ratio of the Ru alloy used for the protective film 3 is 50 atom % or more and less than 100 atom %, preferably 80 atom % or more and less than 100 atom %, and more preferably 95 atom % or more and less than 100 atom %. The protective film 3 in this case can have mask cleaning resistance, an etching stopper function when an absorber film 4 is etched, and a function of preventing the multilayer reflective film 2 from changing with time while sufficiently ensuring a reflectance with respect to EUV light.

In the substrate with a multilayer reflective film 90 of the present embodiment, the protective film 3 preferably contains the same material as the low refractive index layer. In addition, in the substrate with a multilayer reflective film 90 of the present embodiment, the protective film 3 more preferably contains at least one selected from ruthenium (Ru) and rhodium (Rh), and the same additive element (X) as the low refractive index layer.

As described above, the low refractive index layer contains at least one selected from ruthenium (Ru) and rhodium (Rh) and the above-described predetermined additive element X. Therefore, it is preferable that the protective film 3 also contains the same material (RuX, RhX, or RuRhX) as the low refractive index layer. In the substrate with a multilayer reflective film 90 of the present embodiment, by inclusion of the same material as the low refractive index layer in the protective film 3, it can be expected that the protective film 3 functions as a part of the multilayer reflective film 2. Therefore, improvement of the reflectance of the multilayer reflective film 2 can be expected. In addition, by using the same material as the low refractive index layer, the protective film 3 can be more easily formed. Note that it is more preferable that the protective film 3 is made of a material having the same elements and the same composition ratio as those of the low refractive index layer.

The film thickness of the protective film 3 is not particularly limited as long as the function as the protective film 3 can be achieved. From the viewpoint of the reflectance for EUV light, the film thickness of the protective film 3 is preferably 1.0 nm to 8.0 nm and more preferably 1.5 nm to 6.0 nm.

When the protective film 3 is made of a material having the same composition as that of the low refractive index layer, the film thickness of the protective film 3 is preferably the same as the film thickness of the low refractive index layer of the multilayer reflective film 2. In this case, the protective film 3 is preferably formed in contact with a surface of the high refractive index layer of the multilayer reflective film 2. As a result, the protective film 3 can have a function as a part of the multilayer reflective film 2.

When the uppermost layer of the above-described multilayer reflective film 2 is the low refractive index layer, the low refractive index layer as the uppermost layer can also serve as the protective film 3. Since the low refractive index layer of the present embodiment is a thin film containing ruthenium (Ru) and/or rhodium (Rh) and a predetermined additive element as materials, the low refractive index layer can have a function as the protective film 3. Therefore, it is possible to suppress damage to a surface of the multilayer reflective film 2 when the reflective mask 200 (EUV mask) is manufactured using a reflective mask blank 100 described later. Therefore, a reflectance characteristic with respect to EUV light is improved.

As a method for forming the protective film 3, it is possible to adopt a known film forming method without any particular limitation. Specific examples of the method for forming the protective film 3 include an ion beam sputtering method, a magnetron sputtering method, a reactive sputtering method, a vapor phase growth method (CVD), and a vacuum vapor deposition method.

### <Absorber Film 4>

The reflective mask blank 100 of the present embodiment includes the absorber film 4 on the multilayer reflective film 2 of the above-described substrate with a multilayer reflective film 90 or on the protective film 3 formed on the multilayer reflective film 2.

FIG. 3 is a schematic cross-sectional view illustrating an example of the reflective mask blank 100 of the present embodiment. The reflective mask blank 100 illustrated in FIG. 3 includes the absorber film 4 for absorbing EUV light on the multilayer reflective film 2 of the substrate with a multilayer reflective film 90 illustrated in FIG. 1. Note that the reflective mask blank 100 can further include another thin film such as a resist film 11 on the absorber film 4. In a case of the structure illustrated in FIG. 3, an uppermost layer of the multilayer reflective film 2 is preferably a low refractive index layer containing RuX or RuRhX.

FIG. 4 is a schematic cross-sectional view illustrating another example of the reflective mask blank 100 of the present embodiment. The reflective mask blank 100 illustrated in FIG. 4 includes the absorber film 4 for absorbing EUV light on the protective film 3 of the substrate with a multilayer reflective film 90 illustrated in FIG. 2. Note that the reflective mask blank 100 can further include another thin film such as a resist film 11 on the absorber film 4.

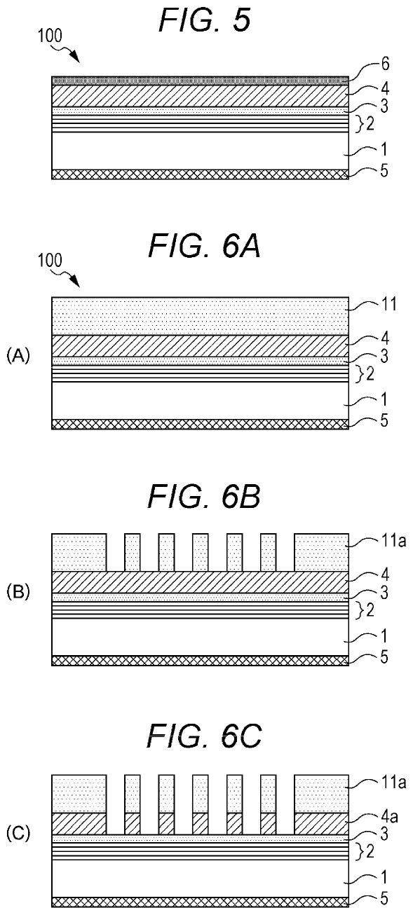

FIG. 5 is a schematic cross-sectional view illustrating another example of the reflective mask blank 100 of the present embodiment. As illustrated in FIG. 5, the reflective mask blank 100 can include an etching mask film 6 on the absorber film 4. Note that the reflective mask blank 100 can further include another thin film such as the resist film 11 on the etching mask film 6.

In the reflective mask blank 100 of the present embodiment, since the absorber film 4 can absorb EUV light, the reflective mask 200 (EUV mask) of the present invention can be manufactured by patterning the absorber film 4 of the reflective mask blank 100. By using the reflective mask blank 100 of the present embodiment, it is possible to obtain the reflective mask blank 100 including the multilayer reflective film 2 having a shallow effective reflective surface and capable of suppressing a phenomenon that atoms to be a material are diffused between the low refractive index layer and the high refractive index layer.

A basic function of the absorber film 4 is to absorb EUV light. The absorber film 4 may be the absorber film 4 for the purpose of absorbing EUV light, or may be the absorber film 4 having a phase shift function in consideration of a phase difference of EUV light. The absorber film 4 having a phase shift function absorbs EUV light and reflects a part of the EUV light to shift a phase. That is, in the reflective mask 200 in which the absorber film 4 having a phase shift function is patterned, in a portion where the absorber film 4 is formed, a part of light is reflected at a level that does not adversely affect pattern transfer while EUV light is absorbed and attenuated. In addition, in a region (field portion) where the absorber film 4 is not formed. EUV light is reflected by the multilayer reflective film 2 (via the protective film 3 when there is the protective film 3). Therefore, a desired phase difference is generated between reflected light from the absorber film 4 having a phase shift function and reflected light from the field portion. The absorber film 4 having a phase shift function is preferably formed such that a phase difference between reflected light from the absorber film 4 and reflected light from the multilayer reflective film 2 is 170 to 260 degrees. Beams of the light having a reversed phase difference interfere with each other at a pattern edge portion, and an image contrast of a projected optical image is thereby improved. As the image contrast is improved, resolution is increased, and various exposure-related margins such as an exposure margin and a focus margin can be increased.

The absorber film 4 may be a single layer film or a multilayer film including a plurality of films (for example, a lower absorber film and an upper absorber film). In a case of a single layer film, the number of steps at the time of manufacturing the mask blank can be reduced, and manufacturing efficiency is increased. In a case of a multilayer film, an optical constant and film thickness of an upper absorber film can be appropriately set such that the upper absorber film serves as an antireflection film at the time of mask pattern defect inspection using light. This improves inspection sensitivity at the time of mask pattern defect inspection using light. In addition, when a film containing oxygen (O), nitrogen (N), and the like that improve oxidation resistance is used as the upper absorber film, temporal stability is improved. As described above, by forming the absorber film 4 into a multilayer film, various functions can be added to the absorber film 4. When the absorber film 4 has a phase shift function, by forming the absorber film 4 into a multilayer film, a range of adjustment on an optical surface can be increased, and therefore a desired reflectance can be easily obtained.

A material of the absorber film 4 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 3. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. The compound may contain the metal or alloy and oxygen (O), nitrogen (N), carbon (C), and/or boron (B).

The absorber film 4 can be formed by a magnetron sputtering method such as a DC sputtering method or an RF sputtering method. For example, the absorber film 4 such as a tantalum compound can be formed by a reactive sputtering method using a target containing tantalum and boron and using an argon gas containing oxygen or nitrogen.

In addition, a crystalline state of the absorber film 4 is preferably an amorphous or microcrystalline structure from a viewpoint of smoothness and flatness. When a surface of the absorber film 4 is not smooth or flat, the absorber pattern 4a may have a large edge roughness and a poor pattern dimensional accuracy. The absorber film 4 has a surface roughness of preferably 0.5 nm or less, more preferably 0.4 nm or less, still more preferably 0.3 nm or less in terms of root mean square roughness (Rms).

### <Etching Mask Film 6>

As illustrated in FIG. 5, the reflective mask blank 100 of the present embodiment can include the etching mask film 6 on the absorber film 4. As a material of the etching mask film 6, a material having a high etching selective ratio (etching rate of absorber film 4/etching rate of etching mask film 6) of the absorber film 4 to the etching mask film 6 is preferably used. The etching selective ratio of the absorber film 4 to the etching mask film 6 is preferably 1.5 or more, and more preferably 3 or more.

The reflective mask blank 100 of the present embodiment preferably includes the etching mask film 6 on the absorber film 4.

As a material of the etching mask film 6, chromium or a chromium compound is preferably used. Examples of the chromium compound include a material containing Cr and at least one element selected from N, O, C, and H. The etching mask film 6 more preferably contains CrN, CrO, CrC, CrON, CrOC, CrCN, or CrOCN, and is still more preferably a CrO-based film containing chromium and oxygen (CrO film. CrON film, CrOC film, or CrOCN film).

As the material of the etching mask film 6, tantalum or a tantalum compound is preferably used. Examples of the tantalum compound include a material containing Ta and at least one element selected from N, O, B, and H. The etching mask film 6 more preferably contains TaN, TaO, TaON, TaBN, TaBO, or TaBON.

As the material of the etching mask film 6, silicon or a silicon compound is preferably used. Examples of the silicon compound include a material containing Si and at least one element selected from N, O, C, and H, a metallic silicon containing a metal in silicon or a silicon compound (metal silicide), a metal silicon compound (metal silicide compound), and the like. Examples of the metal silicon compound include a material containing a metal, Si, and at least one element selected from N, O, C, and H.

The film thickness of the etching mask film 6 is preferably 3 nm or more in order to accurately form a pattern on the absorber film 4. In addition, the film thickness of the etching mask film 6 is preferably 15 nm or less in order to reduce the film thickness of the resist film 11.

### <Conductive Back Film 5>

The conductive back film 5 for electrostatic chuck can be formed on a back surface of the substrate 10 (surface opposite to a side where the multilayer reflective film 2 is formed). Sheet resistance required for the conductive back film 5 for electrostatic chuck is usually 100Ω/□ (22/square) or less. The conductive back film 5 can be formed, for example, by a magnetron sputtering method or an ion beam sputtering method using a target of a metal such as chromium or tantalum or an alloy thereof. A material of the conductive back film 5 is preferably a material containing chromium (Cr) or tantalum (Ta). For example, the material of the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. In addition, the material of the conductive back film 5 is preferably Ta (tantalum), an alloy containing Ta, or a Ta compound containing either Ta or an alloy containing Ta and at least one of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

The film thickness of the conductive back film 5 is not particularly limited as long as the conductive back film 5 functions as a film for electrostatic chuck. The film thickness of the conductive back film 5 is, for example, 10 nm to 200 nm.

### <Reflective Mask 200>

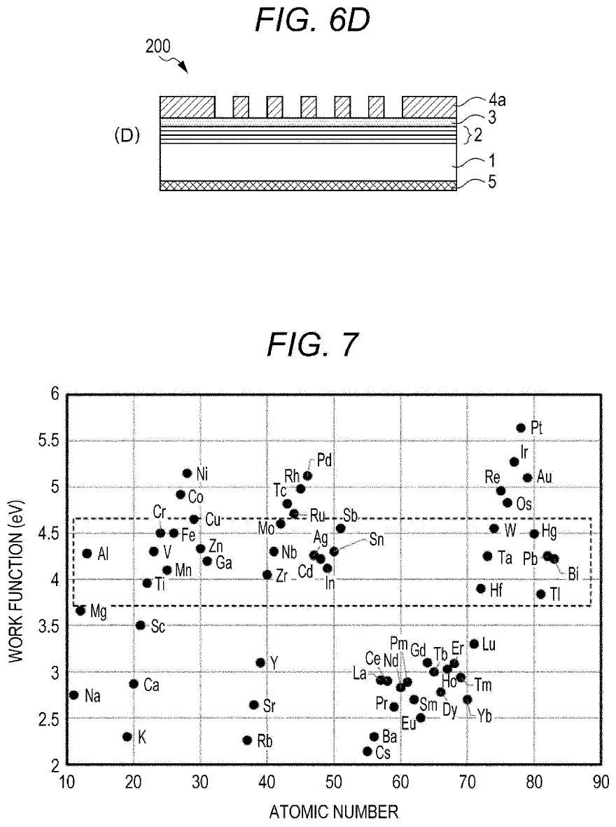

As illustrated in FIG. 6D, the reflective mask 200 of the present embodiment has the absorber pattern 4a obtained by patterning the absorber film 4 of the above-described reflective mask blank 100.

FIGS. 6A to 6D are schematic views illustrating an example of a method for manufacturing the reflective mask 200. Using the above-described reflective mask blank 100 of the present embodiment, the reflective mask 200 of the present embodiment can be manufactured. Hereinafter, an example of a method for manufacturing the reflective mask 200 will be described.

First, the reflective mask blank 100 including the substrate 1, the multilayer reflective film 2 formed on the substrate 1, the protective film 3 formed on the multilayer reflective film 2, and the absorber film 4 formed on the protective film 3 is prepared. Next, the resist film 11 is formed on the absorber film 4 to obtain the reflective mask blank 100 with the resist film 11 (FIG. 6A). A pattern is drawn on the resist film 11 with an electron beam drawing device, and then the resulting product is subjected to a development and rinse step to form a resist pattern 11a (FIG. 6B).

The absorber film 4 is dry-etched using the resist pattern 11a as a mask. As a result, a portion not covered with the resist pattern Ila in the absorber film 4 is etched to form the absorber pattern 4a (FIG. 6C).

As an etching gas for the absorber film 4, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, or the like can be used. As the chlorine-based gas, Cl₂, SiCl₄, CHCl₃, CCl₄, BCl₃, or the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 4a is formed, the resist pattern 11a is removed with a resist peeling liquid. After the resist pattern 11a is removed, the resulting product is subjected to a wet cleaning step using an acidic or alkaline aqueous solution to obtain the reflective mask 200 of the present embodiment (FIG. 6D).

Note that, when the reflective mask blank 100 in which the etching mask film 6 is formed on the absorber film 4 is used, a step of forming a pattern (etching mask pattern) on the etching mask film 6 using the resist pattern 11a as a mask and then forming a pattern on the absorber film 4 using the etching mask pattern as a mask is added.

The reflective mask 200 thus obtained has a structure in which the multilayer reflective film 2, the protective film 3, and the absorber pattern 4a are layered on the substrate 1.

A region where the multilayer reflective film 2 (including the protective film 3) is exposed has a function of reflecting EUV light. A region in which the multilayer reflective film 2 (including the protective film 3) is covered with the absorber pattern 4a has a function of absorbing EUV light. The reflective mask 200 of the present embodiment includes a multilayer reflective film having a shallow effective reflective surface and capable of suppressing a phenomenon that atoms to be a material are diffused between the low refractive index layer and the high refractive index layer. Therefore, by using the reflective mask 200 of the present embodiment, a finer pattern can be transferred onto a transferred object.

### <Method for Manufacturing Semiconductor Device>

A method for manufacturing a semiconductor device of the present embodiment includes a step of performing a lithography process using an exposure apparatus using the above-described reflective mask 200 to form a transfer pattern on a transferred object.

A transfer pattern can be formed on a semiconductor substrate (transferred object) by lithography using the reflective mask 200 of the present embodiment. This transfer pattern has a shape obtained by transferring a pattern of the reflective mask 200. By forming a transfer pattern on a semiconductor substrate with the reflective mask 200, a semiconductor device can be manufactured.

According to the present embodiment, it is possible to manufacture a semiconductor device using the reflective mask 200 including the multilayer reflective film 2 having a shallow effective reflective surface and capable of suppressing a phenomenon that atoms to be a material are diffused between the low refractive index layer and the high refractive index layer. Therefore, by using the reflective mask 200 of the present embodiment, it is possible to increase the density and accuracy of the semiconductor device.

A method for transferring a pattern onto a semiconductor substrate with resist 60 using EUV light will be described with reference to FIG. 9.

FIG. 9 illustrates a schematic configuration of an EUV exposure apparatus 50 that is an apparatus for transferring a transfer pattern onto a resist film formed on the semiconductor substrate 60. In the EUV exposure apparatus 50, an EUV light generation unit 51, an irradiation optical system 56, a reticle stage 58, a projection optical system 57, and a wafer stage 59 are precisely arranged along an optical path axis of EUV light. A container of the EUV exposure apparatus 50 is filled with a hydrogen gas.

The EUV light generation unit 51 includes a laser light source 52, a tin droplet generation unit 53, a catching unit 54, and a collector 55. When a tin droplet emitted from the tin droplet generation unit 53 is irradiated with a high-power carbon dioxide laser from the laser light source 52, tin in a droplet state is turned into plasma to generate EUV light. The generated EUV light is collected by the collector 55, passes through the irradiation optical system 56, and enters the reflective mask 200 set on the reticle stage 58. The EUV light generation unit 51 generates, for example, EUV light having a wavelength of 13.53 nm.

EUV light reflected by the reflective mask 200 is usually reduced to about ¼ of pattern image light by the projection optical system 57 and projected on the semiconductor substrate 60 (transferred substrate). As a result, a given circuit pattern is transferred onto the resist film on the semiconductor substrate 60. The resist film that has been subjected to exposure is developed, whereby a resist pattern can be formed on the semiconductor substrate 60. By etching the semiconductor substrate 60 using the resist pattern as a mask, an integrated circuit pattern can be formed on the semiconductor substrate 60. A semiconductor device is manufactured through such a step and other necessary steps.

### EXAMPLES

Hereinafter, Examples and Comparative Example will be described with reference to the drawings.

(Preparation of Substrates with Multilayer Reflective Film 90 of Examples 1 to 10)

First, the 6025 size (about 152 mm×152 mm×6.35 mm) substrate 1 in which a first main surface and a second main surface were polished was prepared. The substrate 1 is a substrate made of low thermal expansion glass (SiO₂—TiO₂-based glass). The main surfaces of the substrate 1 were polished through a rough polishing step, a precision polishing step, a local processing step, and a touch polishing step.

Next, the multilayer reflective film 2 including a high refractive index layer of Si and a predetermined low refractive index layer was formed on the main surface (first main surface) of the substrate 1. Table 1 presents materials and compositions of the low refractive index layers (RuX or RuRhX, X: additive element) of Examples 1 to 10. A material of the high refractive index layers of Examples 1 to 10 is Si. Table 1 presents a work function of the additive element (X) and the content (atom %) of the additive element (X) in the low refractive index layer.

The multilayer reflective film 2 was formed by an ion beam sputtering method using a Kr gas using a Si target and a RuX target or a RuRhX target (X: additive element). First, the high refractive index layer of Si was formed with a film thickness of 4.2 nm using a Si target so as to be in contact with the main surface of the substrate 1, and subsequently, the low refractive index layer of RuX or RuRhX was formed with a film thickness of 2.8 nm using a RuX target or a RuRhX target (X: additive element). The multilayer reflective film 2 was formed by building up 35 periods (pairs) on the main surface of the substrate 1 when one high refractive index layer and one low refractive index layer were taken as one period.

Next, a RuRhNb film was formed as the protective film 3 on each of the multilayer reflective films 2 of Examples 1 to 10. The protective film 3 was formed with a thickness of 3.5 nm using a RuRhNb target in an Ar gas atmosphere by a magnetron sputtering method. A composition ratio (atom %) of the protective film 3 is Ru:Rh:Nb=64:16:20.

The substrates with a multilayer reflective film 90 of Examples 1 to 10 were manufactured as described above.

### Preparation of Substrates with Multilayer Reflective Film 90 of Comparative Examples 1 and 2

The substrate with a multilayer reflective film 90 was manufactured in a similar manner to Examples 1 to 10 except that Ru (Comparative Example 1) or RuRh (Comparative Example 2) was used as the material of the low refractive index layer. Therefore, each of the low refractive index layers of Comparative Examples 1 and 2 does not contain the additive element (X). Note that a Ru target was used when the low refractive index layer of Comparative Example 1 was used, and a RuRh target was used when the low refractive index layer of Comparative Example 2 was used. Table 1 presents a composition ratio (atom %) of each of the low refractive index layers of Comparative Examples 1 and 2.

(Evaluation of Reflectance of Substrate with Multilayer Reflective Film 90)

Using the substrates with a multilayer reflective film 90 of Examples and Comparative Examples prepared as described above, a change in reflectance due to heat treatment to the substrates with a multilayer reflective film 90 was measured.

Specifically, first, a reflectance (R1, unit: %) of each of the substrates with a multilayer reflective film 90 of Examples and Comparative Examples with respect to EUV light (wavelength: 13.5 nm) was measured. Next, the substrate with a multilayer reflective film 90 was subjected to heat treatment by being heated at 200° C. for 10 minutes in the air atmosphere. After the substrate with a multilayer reflective film 90) was subjected to the heat treatment, a reflectance (R2, unit: %) of the substrate with a multilayer reflective film 90 with respect to EUV light was measured. By subtracting a value of the reflectance (R2) of the substrate with a multilayer reflective film 90 after the heat treatment from a value of the reflectance (R1) of the substrate with a multilayer reflective film 90 before the heat treatment, a change in EUV reflectance of the substrate with a multilayer reflective film 90 due to the heat treatment was obtained. Table 1 presents a change in EUV reflectance due to the heat treatment.

As presented in Table 1, in the substrates with a multilayer reflective film 90 of Examples 1 to 10, the reflectance with respect to EUV light changed by 9.4% (Example 7) or less after the heat treatment at 200° C. for 10 minutes as compared with that before the heat treatment. Since the material of the low refractive index layer of each of the multilayer reflective films 2 of Examples 1 to 10 was RuX or RuRhX containing a predetermined additive element (X), diffusion of Si from the high refractive index layer to the low refractive index layer was suppressed. Therefore, it is presumed that the reflectance slightly changed after the heat treatment as compared with that before the heat treatment. In particular, the change in the reflectance of Example 1 in which the material of the low refractive index layer was RuNb was as small as 6.9%.

Meanwhile, in the substrates with a multilayer reflective film 90 of Comparative Examples 1 and 2, the reflectance of the substrate with a multilayer reflective film 90 with respect to EUV light largely changed after the heat treatment at 200° C. for 10 minutes as compared with that before the heat treatment. In Comparative Examples 1 and 2, it is presumed that Si was diffused from the high refractive index layer to the low refractive index layer, a metal silicide (RuSi or RuRhSi) was formed in the high refractive index layer, and the reflectance thereby largely changed.

(Reflective mask blank 100)

Next, the reflective mask blanks 100 of Examples 1 to 10 will be described.

By forming the conductive back film 5 on a back surface of the substrate 1 of the substrate with a multilayer reflective film 90 manufactured as described above, and forming the absorber film 4 on the protective film 3, the reflective mask blanks 100 of Examples 1 to 10 were manufactured.

First, the conductive back film 5 constituted by a CrN film was formed on the second main surface (back surface) of the substrate 1 of the substrate with a multilayer reflective film 90 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

Next, a TaBN film having a film thickness of 55 nm was formed as the absorber film 4 on the protective film 3 of the substrate with a multilayer reflective film 90. A composition of the absorber film 4 was Ta:B:N=75:12:13 (atomic ratio), and the absorber film 4 had a film thickness of 55 nm.

As described above, the reflective mask blanks 100 of Examples 1 to 10 were manufactured.

### (Reflective Mask 200)

Next, the reflective mask 200 was manufactured using each of the reflective mask blanks 100 of Examples 1 to 10. The manufacture of the reflective mask 200 will be described with reference to FIGS. 6A to 6D.

First, as illustrated in FIG. 6A, the resist film 11 was formed on the absorber film 4 of the reflective mask blank 100. Then, a desired pattern such as a circuit pattern was drawn (exposed) on the resist film 11 and further developed and rinsed to form the predetermined resist pattern 11a. (FIG. 6B). Next, using the resist pattern 11a as a mask, the absorber film 4 (TaBN film) was dry-etched using Cl₂ gas to form the absorber pattern 4a (FIG. 6C). Next, the resist pattern 11a was removed (FIG. 6D).

Finally, wet cleaning was performed with deionized water (DIW) to manufacture each of the reflective masks 200 of Examples 1 to 10.

### (Manufacture of Semiconductor Device)

The reflective masks 200 of Examples 1 to 10 were each set in an EUV scanner, and EUV exposure was performed on a wafer on which a film to be processed and a resist film were formed on the semiconductor substrate 60 which is a transferred object. Then, this resist film that had been subjected to exposure was developed to form a resist pattern on the semiconductor substrate 60 on which the film to be processed was formed.

The reflective masks 200 of Examples 1 to 10 each include the multilayer reflective film 2 having a shallow effective reflective surface and capable of suppressing a phenomenon that atoms to be a material are diffused between the low refractive index layer and the high refractive index layer. Therefore, a fine and highly accurate transfer pattern (resist pattern) could be formed on the semiconductor substrate 60 (transferred substrate).

This resist pattern was transferred onto the film to be processed by etching, and through various steps such as formation of an insulating film and a conductive film, introduction of a dopant, and annealing, a semiconductor device having desired characteristics could be manufactured at a high yield.

TABLE 1

| | | | | | | Change in |
|---|---|---|---|---|---|---|
| | | | | | Content of X | EUV |
| | Low | | | Composition ratio | in low | reflectance |
| | refractive | Additive | Work | of low refractive | refractive | due to heat |
| | index | element | function of | index layer | index layer | treatment |
| | layer | (X) | X (eV) | (atom %) | (atom %) | (R1-R2) (%) |
| Example 1 | Ru | Nb | 4.3 | Ru:Nb = 80:20 | 20 | 6.9 |
| Example 2 | Ru | Mo | 4.6 | Ru:Mo = 60:40 | 40 | 8.3 |
| Example 3 | Ru | Ti | 3.96 | Ru:Ti = 95:5 | 5 | 8.6 |
| Example 4 | Ru | Ta | 4.25 | Ru:Ta = 95:5 | 5 | 9.1 |
| Example 5 | Ru | Cr | 4.5 | Ru:Cr = 90:10 | 10 | 9.2 |
| Example 6 | RuRh | Nb | 4.3 | Ru:Rh:Nb = 64: | 20 | 7.4 |
| | | | | 16:20 | | |
| Example 7 | RuRh | Mo | 4.6 | Ru:Rh:Mo = 48: | 40 | 9.4 |
| | | | | 12:40 | | |
| Example 8 | RuRh | Ti | 3.96 | Ru:Rh:Ti = 68: | 15 | 7.3 |
| | | | | 17:15 | | |
| Example 9 | RuRh | Ta | 4.25 | Ru:Rh:Ta = 68: | 15 | 9.0 |
| | | | | 17:15 | | |
| Example 10 | RuRh | Cr | 4.5 | Ru:Rh:Cr = 56: | 30 | 8.9 |
| | | | | 14:30 | | |
| Comparative | Ru | — | — | Ru =100 | 0 | 10.0 |
| Example 1 | | | | | | |
| Comparative | RuRh | — | — | Ru:Rh = 80:20 | 0 | 11.9 |
| Example 2 | | | | | | |

TABLE 2

| | | | | | | Lower | Upper |
|---|---|---|---|---|---|---|---|
| | | | | | | limit of | limit of |
| | Work | Refractive | Extinction | Diffusion | Optical | addition | addition |
| Additive | function | index | coefficient | preventing | characteristic | amount | amount |
| element (X) | of X (eV) | (n) | (k) | group | group | (atom %) | (atom %) |
| Tl | 3.84 | 0.937 | 0.043 | A | b | 1 | 30 |
| Hf | 3.9 | 0.961 | 0.035 | A | c | 1 | 15 |
| Ti | 3.96 | 0.953 | 0.017 | A | b | 1 | 30 |
| Zr | 4.05 | 0.958 | 0.004 | A | a | 1 | 50 |
| Mn | 4.1 | 0.934 | 0.031 | A | b | 1 | 30 |
| In | 4.12 | 0.931 | 0.071 | A | b | 1 | 30 |
| Ga | 4.2 | 0.986 | 0.038 | A | c | 1 | 15 |
| Cd | 4.22 | 0.928 | 0.055 | A | b | 1 | 30 |
| Bi | 4.22 | 0.944 | 0.056 | A | c | 1 | 15 |
| Ta | 4.25 | 0.943 | 0.041 | A | b | 1 | 30 |
| Pb | 4.25 | 0.935 | 0.050 | A | b | 1 | 30 |
| Ag | 4.26 | 0.890 | 0.079 | A | b | 1 | 30 |
| Al | 4.28 | 1.003 | 0.030 | A | c | 1 | 15 |
| V | 4.3 | 0.945 | 0.024 | A | b | 1 | 30 |
| Nb | 4.3 | 0.934 | 0.005 | A | a | 1 | 50 |
| Sn | 4.3 | 0.942 | 0.072 | A | c | 1 | 15 |
| Zn | 4.33 | 0.974 | 0.056 | B | c | 4 | 15 |
| Hg | 4.49 | 0.933 | 0.045 | B | b | 4 | 30 |
| Cr | 4.5 | 0.932 | 0.039 | B | b | 4 | 30 |
| Fe | 4.5 | 0.941 | 0.052 | B | c | 4 | 15 |
| Sb | 4.55 | 0.945 | 0.068 | C | c | 8 | 15 |
| W | 4.55 | 0.930 | 0.042 | C | b | 8 | 30 |
| Mo | 4.6 | 0.920 | 0.010 | C | a | 8 | 50 |
| Cu | 4.65 | 0.963 | 0.061 | C | c | 8 | 15 |

### REFERENCE SIGNS LIST

1 Substrate
2 Multilayer reflective film
3 Protective film
4 Absorber film
4a Absorber pattern
5 Conductive back film
6 Etching mask film
11 Resist film
11a Resist pattern
50 EUV exposure apparatus
51 EUV light generation unit
52 Laser light source
53 Tin droplet generation unit
54 Catching unit
55 Collector
56 Irradiation optical system
57 Projection optical system
58 Reticle stage
59 Wafer stage
60 Semiconductor substrate
90 Substrate with a multilayer reflective film
100 Reflective mask blank
200 Reflective mask

1. A substrate with a multilayer reflective film comprising a substrate and a multilayer reflective film formed on the substrate, wherein
the multilayer reflective film comprises a multilayer film in which a low refractive index layer comprising at least one selected from ruthenium (Ru) and rhodium (Rh) and a high refractive index layer comprising silicon (Si) are alternately layered, and
the low refractive index layer further comprises an additive element having a work function in a range of more than 3.7 eV and less than 4.7 eV.

2. The substrate with a multilayer reflective film according to claim 1, wherein the low refractive index layer comprises at least one additive element selected from thallium (Tl), hafnium (Hf), titanium (Ti), zirconium (Zr), manganese (Mn), indium (In), gallium (Ga), cadmium (Cd), bismuth (Bi), tantalum (Ta), lead (Pb), silver (Ag), aluminum (Al), vanadium (V), niobium (Nb), tin (Sn), zinc (Zn), mercury (Hg), chromium (Cr), iron (Fe), antimony (Sb), tungsten (W), molybdenum (Mo), and copper (Cu).

3. The substrate with a multilayer reflective film according to claim 1 or 2, wherein when a stack of the low refractive index layer and the high refractive index layer is taken as one period, the stack is layered for less than 40 periods.

4. The substrate with a multilayer reflective film according to any one of claims 1 to 3, comprising a protective film on the multilayer reflective film.

5. The substrate with a multilayer reflective film according to claim 4, wherein the protective film comprises the same material as the low refractive index layer.

6. The substrate with a multilayer reflective film according to claim 4 or 5, wherein the protective film comprises at least one selected from ruthenium (Ru) and rhodium (Rh), and the same additive element as the low refractive index layer.

7. A reflective mask blank comprising an absorber film on the protective film of the substrate with a multilayer reflective film according to any one of claims 4 to 6.

8. A reflective mask blank comprising an absorber film on the multilayer reflective film of the substrate with a multilayer reflective film according to any one of claims 1 to 3.

9. A reflective mask comprising an absorber pattern obtained by patterning the absorber film of the reflective mask blank according to claim 7 or 8.

10. A method for manufacturing a semiconductor device, comprising performing a lithography process with an exposure apparatus using the reflective mask according to claim 9 to form a transfer pattern on a transferred object.
